(19) United States
(12) Patent Application Publication
(10) Pub. No.: US 2026/0171178 A1
(43) Pub. Date: Jun. 18, 2026

(54) SELECT GATE SCANNING USING FAILED BIT COUNT

(71) Applicant: Micron Technology, Inc., Boise, ID (US)

(72) Inventors: Tawalin Opastrakoon, Boise, ID (US); Sean Brasfield, Boise, ID (US); Chong Giap Chiew, Santa Clara, CA (US); Zhi Yin Chiew, Singapore (SG)

(21) Appl. No.: 18/984,754

(22) Filed: Dec. 17, 2024

(51) Int. Cl. G11C 29/12

(52) U.S. Cl. CPC G11C 29/12005

(57) ABSTRACT

Methods, systems, and apparatuses include sending a select gate scan command to a memory device to cause the memory device to perform a select gate scan at a select gate bias voltage on a memory portion of the memory device. A failed bit count is received from the memory device. It is determined that the failed bit count satisfies a refresh threshold. A refresh operation is performed on the memory portion in response to determining that the failed bit count satisfies the refresh threshold.

### TECHNICAL FIELD

The present disclosure generally relates to select gate scanning, and more specifically, relates to select gate scanning using failed bit counts.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 illustrates another example computing system that includes an adaptive select gate scanning component in accordance with some embodiments of the present disclosure.

FIG. 3 is a flow diagram of an example method to perform select gate scanning using failed bit counts in accordance with some embodiments of the present disclosure.

FIG. 4 is another flow diagram of an example method to perform select gate scanning using failed bit counts in accordance with some embodiments of the present disclosure.

FIG. 5 is a block diagram of an example computer system in which embodiments of the present disclosure may operate.

### DETAILED DESCRIPTION

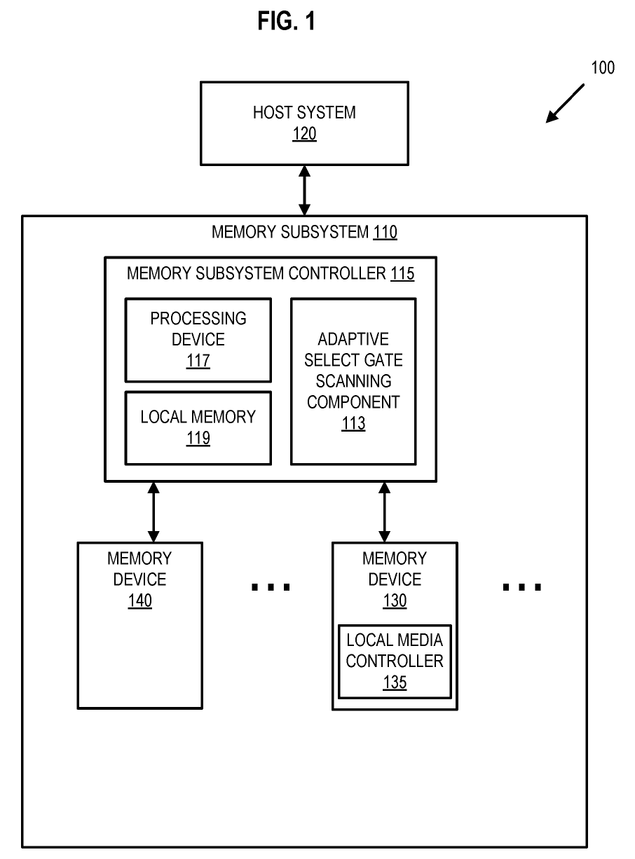

Aspects of the present disclosure are directed to performing select gate scans using failed bit counts for memory devices in a memory subsystem. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1 . The dice in the packages can be assigned to one or more channels for communicating with a memory subsystem controller. Each die can consist of one or more planes. Planes can be grouped into logic units identified by a logical unit number (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information and has various logic states that correlate to the number of bits being stored. The logic states can be represented by binary values, such as "0" and "1", or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store sixteen bits of information and has sixteen logic states.

In conventional memory systems, memory blocks are programmed, erased, and/or otherwise subject to read disturb, such as due to environmental factors of the memory system (e.g., temperature) and operations performed on neighboring memory blocks. This read disturb can result in charge trapping in the insulating layer between the select gate and the channel, causing the select gate threshold voltage to increase and requiring increasingly higher select gate bias voltages to activate the select gates of the memory blocks. Select gate threshold voltages that are too high can pinch off the channel resulting in memory operation failure and potentially permanent loss of data. Conventional memory systems can communicate with the memory devices to perform select gate scans but only use binary results for the select gate scan (e.g., whether select gate scan voltage exceeds threshold). Because the threshold and the results of the select gate scan are internal to the memory device, the memory subsystem cannot change the threshold or analyze the results of the scan. Furthermore, conventional memory subsystems only determine whether to retire the memory block based on the binary results of the select gate scan.

Aspects of the present disclosure address the above and other deficiencies by performing select gate scanning using failed bit counts. The memory subsystem sends a configurable select gate scan command to the memory device which causes the memory device to perform the select gate scan and store the results of the select gate scan (e.g., failed bit count for the select gate scan voltage) in a memory cache accessible by the memory subsystem. The memory subsystem can thereby use the results of the select gate scan to determine whether to perform a refresh operation on the select gate, retire the affected memory block, adjust intervals at which the select gate scan operation is performed, etc. Additionally, because the select gate scan command is configurable, the memory subsystem can change aspects of the select gate scan command to fit specific criteria. For example, the memory subsystem can set different failed bit count thresholds for different types of select gates and/or indicate specific memory addresses within a memory block to perform the select gate scan on. These improvements result in memory subsystems with more dynamic approaches to select gate scanning, leading to reductions in memory block retirement, increased select gate scan efficiency, and more proactive responses to select gate threshold voltage degradation.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processing device such as a processor chipset and a software stack executed by the processor chipset. The processor chipset can include one or more cores, one or more caches, a memory controller (e.g., NVDIMM controller), and/or a storage protocol controller (e.g., a peripheral component interconnect express (PCIe) controller, a serial advanced technology attachment (SATA) controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a SATA interface, including a mini-SATA (mSATA) interface, a PCIe interface, including a mini PCIe (mPCIE) interface, a Non-Volatile Memory Express (NVMe) interface, a universal serial bus (USB) interface, an a Fibre Channel, Serial Attached SCSI (SAS), a Small Computer System Interface (SCSI), a double data rate (DDR) memory bus, a dual in-line memory module (DIMM) interface (e.g., DIMM socket interface that supports Double Data Rate (DDR)),an Advanced Host Controller (AHCI) interface, an Open NAND Flash Interface (ONFI) interface, a Double Data Rate (DDR) interface, a Low Power Double Data Rate (LPDDR) interface, any other interface, and/or combinations of these interfaces. The physical host interface can be used to transmit data between the host system 120 and the memory subsystem 110. The host system 120 can further utilize an NVMe interface to access components (e.g., memory devices 130 and 140) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via the same communication connection, multiple separate communication connections, and/or a combination of communication connections.

The memory devices 130 and 140 can include any combination of the different types of non-volatile memory devices and/or volatile memory devices. The volatile memory devices (e.g., memory device 140) can be, but are not limited to, random-access memory (RAM), such as dynamic random-access memory (DRAM), synchronous dynamic random-access memory (SDRAM), video random-access memory (VRAM), and cache memory.

Some examples of non-volatile memory devices (e.g., memory device 130) include negative-and (NAND) type flash memory devices and write-in-place type memory devices, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random-access memory (FeRAM), magneto random-access memory (MRAM), Spin Transfer Torque (STT)-MRAM, nano-RAM (NRAM), silicon-oxide-nitride-oxide-silicon (SONOS) memory, conductive bridging RAM (CBRAM), resistive random-access memory (RRAM), oxide based RRAM (OxRAM), negative-or (NOR) flash memory, and erasable programmable read-only memory (EPROM), including electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The buffer memory of subsystem controller 115 can include any of the volatile or non-volatile memory types mentioned above including combinations thereof. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in memory subsystem 110 (e.g., stored in a local memory 119). In some examples, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processing device or controller separate from the memory subsystem 110).

In general, the memory subsystem controller 115 can receive commands or operations from the host system 120 and can convert the commands or operations into instructions or appropriate commands to achieve the desired access to the memory devices (e.g., memory devices 130 and/or 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA) and/or namespace) and a physical address (e.g., physical block address) that are associated with the memory devices (e.g., memory devices 130 and/or 140). The memory subsystem controller 115 can further include host interface circuitry to communicate with the host system 120 via the physical host interface. The host interface circuitry can convert the commands received from the host system into command instructions to access the memory devices (e.g., memory devices 130 and/or 140) as well as convert responses associated with the memory devices into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices (e.g., memory devices 130 and/or 140).

In some embodiments, the memory devices (e.g., memory devices 130 and/or 140) include local media controllers 135 that operate in conjunction with memory subsystem controller 115 to execute operations on one or more memory cells of the memory devices (e.g., memory devices 130 and/or 140). An external controller (e.g., memory subsystem controller 115) can externally manage the memory devices (e.g., perform media management operations on the memory devices 130 and/or 140). In some embodiments, a memory device (e.g., memory device 130) is a managed memory device, which is a raw memory device combined with a local controller (e.g., local controller 135) for media management within the same memory device package. An example of a managed memory device is a managed NAND (MNAND) device.

The memory subsystem 110 includes an adaptive select gate scanning component 113 that sends select gate scan commands, determines failed bit counts resulting from the select gate scan commands, and performs memory operations based on the failed bit counts. In some embodiments, the controller 115 includes at least a portion of the adaptive select gate scanning component 113. For example, the controller 115 can include a processing device 117 configured to execute instructions stored in local memory 119 for performing the operations described herein. In some embodiments, an adaptive select gate scanning component 113 is part of the host system 120, an application, or an operating system.

The adaptive select gate scanning component 113 configures and sends select gate scan commands causing memory devices to perform select gate scans using the parameters from the select gate scan commands. Adaptive select gate scanning component 113 uses the results from these select gate scans to determine operations to perform on the memory subsystem 110 and/or memory device. Further details regarding the operations of the adaptive select gate scanning component 113 are described below.

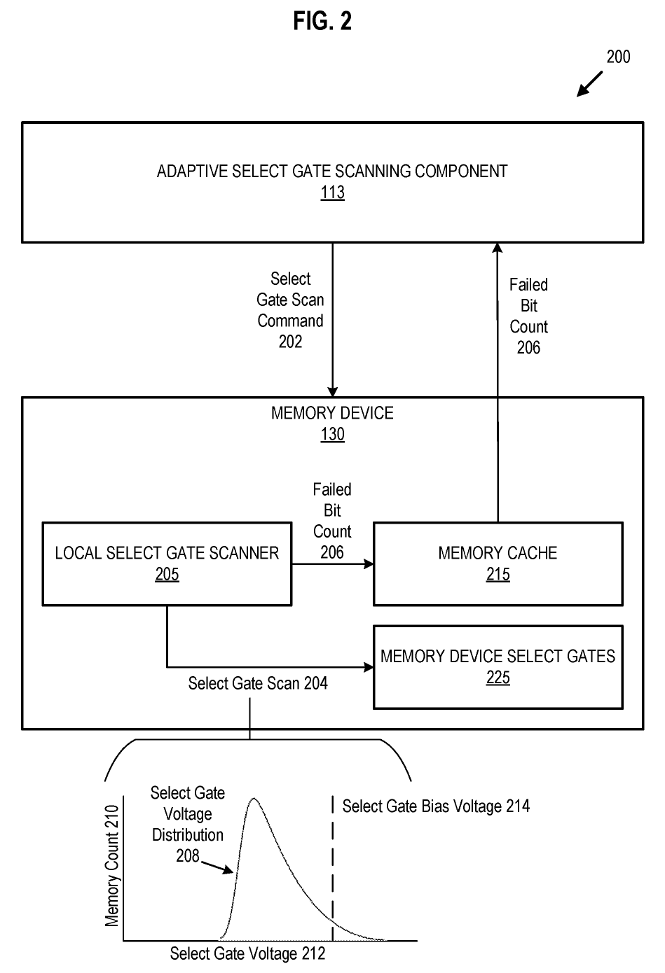

FIG. 2 illustrates another example computing system that includes an adaptive select gate scanning component in accordance with some embodiments of the present disclosure. As shown in FIG. 2, computing system 200 includes adaptive select gate scanning component 113 and memory device 130. Memory device 130 includes local select gate scanner 205, memory cache 215, and memory device select gates 225. Local select gate scanner 205 includes circuitry of memory device 130 allowing memory device to perform a select gate scan on memory device select gates 225 of memory device 130. For example, local select gate scanner 205 includes circuitry to apply a select gate bias voltage (e.g., select gate bias voltage 214) to memory device select gates 225 of memory device 130. In such an example, local select gate scanner 205 can also include circuity to determine a number of bits of memory device select gates 225 with threshold voltages that exceed select gate bias voltage 214.

In some embodiments, memory cache 215 is a memory cache of memory device 130 accessible by adaptive select gate scanning component 113. For example, memory device 130 is coupled with adaptive select gate scanning component 113 such that adaptive select gate scanning component 113 can retrieve data from memory cache 215, such as failed bit count 206. In some embodiments, memory cache 215 is a memory portion of memory device 130 with a faster response time when compared to other memory portions of memory device 130. For example, memory cache 215 is implemented as a RAM or DRAM memory portion coupled to adaptive select gate scanning component 113.

Adaptive select gate scanning component 113 sends select gate scan command 202 to memory device 130. For example, adaptive select gate scanning component 113 sends a command to memory device 130 to cause memory device 130 to perform a select gate scan on a memory portion of memory device 130. In some embodiments, adaptive select gate scanning component 113 sends select gate scan command 202 in response to determining that a program erase cycle count for a memory portion of memory device 130 satisfies a program erase cycle threshold. For example, adaptive select gate scanning component 113 retrieves a program erase cycle threshold for the memory portion and compares the program erase cycle count with the program erase cycle threshold. In such embodiments, if adaptive select gate scanning component 113 determines that the program erase cycle count for a memory portion exceeds the program erase cycle threshold for that memory portion, adaptive select gate scanning component 113 sends select gate scan command 202 to the memory device including that memory portion (e.g., memory device 130). In some embodiments, adaptive select gate scanning component 113 sends select gate scan command 202 in response to a memory operation failure. For example, adaptive select gate scanning component 113 sends select gate scan command 202 in response to memory device 130 failing during a memory read, write, or erase operation.

In some embodiments, select gate scan command 202 includes a select gate bias voltage 214. For example, adaptive select gate scanning component 113 sends select gate scan command 202 to memory device 130 to cause memory device 130 to perform a select gate scan 204 at the select gate bias voltage 214 included in select gate scan command 202. In some embodiments, memory device 130 stores bias voltage 214 for future use. For example, memory device 130 stores bias voltage 214 to use for future select gate scans. In some embodiments, memory device 130 retrieves the stored bias voltage 214 in response to determining that the select gate scan command 202 does not include a bias voltage. In some embodiments, the bias voltage is stored at a time of manufacture. For example, select gate bias voltage 214 is programmed to a designated portion of memory device 130 at a time of manufacture (e.g., by adaptive select gate scanning component 113 and/or memory subsystem controller 115).

In some embodiments, in response to receiving select gate scan command 202 including select gate bias voltage 214 from adaptive select gate scanning component 113, memory device 130 updates the previous select gate bias voltage (e.g., the select gate bias voltage stored at the time of manufacture). In such embodiments, memory device 130 uses the received select gate bias voltage 214 for future select gate scan commands until it receives a new select gate bias voltage or receives some other command to update the select gate bias voltage. For example, memory device 130 uses the received select gate bias voltage 214 for future select gate scans performed in response to select gate scan commands which do not include an updated select gate bias voltage.

In some embodiments, adaptive select gate scanning component 113 sends select gate scan command 202 including a bias voltage restore request. In such embodiments, memory device 130 restores the stored select gate bias voltage to a previous value in response to receiving the select gate scan command 202 including the bias voltage restore request. For example, memory device 130 restores the stored select gate bias voltage to the value stored at the time of manufacture in response to receiving the select gate scan command 202 including the bias voltage restore request. In some embodiments, memory device 130 stores the select gate bias voltage through a process separate from select gate scan command 202. For example, memory device stores an updated select gate bias voltage in response to receiving a command other than a select gate scan command (e.g., from adaptive select gate scanning component 113 and/or memory subsystem controller 115) or in response to some process internal to memory device 130 (e.g., in response to tracking metrics reaching a threshold).

In some embodiments, adaptive select gate scanning component 113 determines the select gate bias voltage 214 using a program erase cycle count. For example, adaptive select gate scanning component 113 retrieves a program erase cycle count for the memory portion associated with memory device select gates 225 from a look-up table and determines select gate bias voltage 214 using the retrieved program erase cycle count.

In some embodiments, select gate scan command 202 includes a scan address identifying which select gates of the memory device select gates 225 to scan. For example, adaptive select gate scanning component 113 determines that a program erase cycle count for a memory portion exceeds a program erase cycle threshold for performing a select gate scan. In such an example, adaptive select gate scanning component 113 determines a scan address as the memory address for the memory portion where the program erase cycle count exceeds the program erase cycle threshold and sends select gate scan command 202 including the scan address to memory device 130.

In some embodiments, adaptive select gate scanning component 113 determines the scan address based on defectivity information for the memory device select gates 225. For example, adaptive select gate scanning component 113 includes a lookup table with defectivity value information indicating how sensitive to threshold voltage shift each of the select gates of memory device select gates 225 are. For example, adaptive select gate scanning component 113 retrieves a lookup table with addresses identifying different select gates for the memory portion and associated defectivity values. In such an example, adaptive select gate scanning component 113 determines a scan address identifying select gates that are most sensitive to threshold voltage shift and includes the scan address in the select gate scan command 202. Accordingly, adaptive select gate scanning component 113 can ensure that the select gates most susceptible to threshold voltage drift are scanned while not wasting time scanning the select gates that are less susceptible.

In some embodiments, adaptive select gate scanning component 113 updates defectivity values (e.g., based on the failed bit count 206 results of a select gate scan). In some embodiments, adaptive select gate scanning component 113 determines the scan address as the addresses for the subset of select gates with defectivity values that satisfy a defectivity threshold. For example, adaptive select gate scanning component 113 determines the scan address as the addresses of the subset of select gates with defectivity values greater than a defectivity threshold. In some embodiments, adaptive select gate scanning component 113 determines the scan address as the addresses for a given number (e.g., subset) of select gates with defectivity values indicating they are most susceptible to voltage drift. For example, adaptive select gate scanning component 113 uses a scan address count to determine the scan address as the addresses for a number of select gates with defectivity values indicating they are most susceptible to voltage drift, when the number of select gates is the scan address count.

In some embodiments, adaptive select gate scanning component 113 determines the scan address using a scan time threshold. For example, adaptive select gate scanning component 113 determines that the time required to perform a select gate scan operation on the full memory portion (e.g., every select gate for the memory portion where the program erase cycle count exceeds the program erase cycle threshold) exceeds a scan time threshold for the computing system 200. In such an example, adaptive select gate scanning component 113 determines a scan address indicating a subset of select gates to scan such that the time required to perform a select gate scan operation on the subset of select gates does not exceed the scan time threshold. In some embodiments, adaptive select gate scanning component 113 determines the subset of select gates using defectivity information as explained above.

In some embodiments, adaptive select gate scanning component 113 determines the select gate bias voltage 214 using a select gate type for memory device select gates 225. For example, adaptive select gate scanning component 113 can determine a select gate bias voltage for selector select gates and a different select gate bias voltage for generator select gates. By using different select gate bias voltages for selectors and generators, adaptive select gate scanning component 113 can, for example, reduce the frequency of refresh operations for generators while maintaining the frequency of refresh operations for selectors. Because a voltage shift in selectors results in more data loss than the same voltage shift in generators, by selecting gate bias voltage based on the select gate type, adaptive select gate scanning component 113 can optimize the resources spent on refresh operations (e.g., time and power) with the potential for data loss due to voltage shift.

In some embodiments, the select gate types include a source side select gate type and a drain side select gate type. For example, adaptive select gate scanning component 113 determines a select gate type of a source side select gate type or a drain side select gate type for one or more of memory device select gates 225. In such embodiments, adaptive select gate scanning component 113 determines the select gate bias voltage 214 using the select gate type. For example, adaptive select gate scanning component 113 determines a lower select gate bias voltage 214 for drain side select gate types and a higher select gate bias voltage 214 for source side select gate types. In such an example, because the select gate bias voltage 214 is lower for drain side select gate types, the system is more sensitive to voltage shifts and more likely to perform a refresh operation.

In some embodiments, select gate scan command 202 includes a refresh operation indicator. For example, adaptive select gate scanning component 113 sends select gate scan command 202 to memory device 130 indicating whether to perform a select gate scan or a select gate refresh operation. In one embodiment, in response to receiving a select gate scan command including a refresh operation indicator, memory device 130 performs a refresh operation of memory device select gates 225. For example, local select gate scanner erases and reprograms memory device select gates 225. In some embodiments, memory device 130 performs a select gate scan 204 in response to performing the refresh operation. In some embodiments, adaptive select gate scanning component 113 sends a select gate scan command 202 to cause memory device 130 to perform select gate scan 204 in response to memory device 130 performing a refresh operation on memory device select gates 225.

In response to receiving select gate scan command 202 from adaptive select gate scanning component 113, memory device 130 performs a select gate scan 204 on memory device select gates 225. For example, local select gate scanner 205 applies a select gate bias voltage 214 to memory device select gates 225 to detect select gates of memory device select gates 225 with select gate voltages (e.g., select gate voltage 212) greater than select gate bias voltage 214. FIG. 2 illustrates an example of a select gate voltage distribution 208 with the y axis corresponding with bit count 210 (e.g., the number of memory cells) for select gates at a given select gate voltage 212 represented by the x axis. As shown in FIG. 2, local select gate scanner 205 performs a select gate scan 204 on memory device select gates to identify the number of memory device select gates with select gate voltages 212 above select gate bias voltage 214. Based on the bit count 210 for select gate voltages 212 above select gate bias voltage 214, local select gate scanner 205 determines failed bit count 206. For example, failed bit count 206 is a count of the number of select gates with select gate voltages that exceed select gate bias voltage 214 (e.g., represented as the area under the curve of the select gate voltage distribution 208 above select gate bias voltage 214). As explained above, in some embodiments, local select gate scanner 205 performs select gate scan 204 on a subset of the select gates from memory device select gates 225. For example, local select gate scanner 205 performs select gate scan 204 on the select gates identified in a scan address included in select gate scan command 202.

In some embodiments, in response to determining failed bit count 206, local select gate scanner 205 stores failed bit count 206 in memory cache 215 accessible by adaptive select gate scanning component 113. In some embodiments, in response to performing select gate scan 204 and/or determining failed bit count 206, memory device 130 sends an indicator to adaptive select gate scanning component 113 that memory device 130 has completed select gate scan command 202. In such embodiments, in response to receiving the indicator, adaptive select gate scanning component 113 receives failed bit count 206 (e.g., by retrieving failed bit count 206 from memory cache 215). In some embodiments, select gate scanning component 113 receives failed bit count 206 from memory device 130(e.g., memory device 130 sends failed bit count 206 to select gate scanning component 113).

In some embodiments, in response to performing select gate scan 204 and/or determining failed bit count 206, memory device 130 updates an internal indicator in a memory portion accessible to adaptive select gate scanning component 113 (e.g., memory cache 215). For example, memory device 130 updates an indicator showing that it is ready and/or no longer busy. In such embodiments, in response to checking the indicator, adaptive select gate scanning component 113 receives failed bit count 206 by retrieving failed bit count 206 from memory cache 215 of memory device 130.

In response to receiving failed bit count 206, adaptive select gate scanning component 113 determines whether failed bit count 206 satisfies a refresh threshold. For example, adaptive select gate scanning component 113 retrieves a refresh threshold associated with memory device select gates 225 and determines whether failed bit count 206 is greater than the retrieved refresh threshold. In such an example, if failed bit count 206 is greater than the retrieved refresh threshold, adaptive select gate scanning component 113 sends a command for memory device 130 to perform a refresh operation (e.g., adaptive select gate scanning component 113 sends a select gate scan command including a refresh indicator to memory device 130). In some embodiments, the command to perform a refresh operation indicates the same select gates as the select gate scan command 202 (e.g., as indicated by the scan address). In some embodiments, the command to perform a refresh operation includes a refresh address which identified select gates to perform the refresh operation on. Memory device 130 performs a refresh operation by erasing and reprogramming the select gates (e.g., the select gates identified by the refresh operation and/or select gate scan command 202).

In some embodiments, in response to memory device 130 performing the refresh operation, adaptive select gate scanning component 113 sends another select gate scan command 202 to memory device 130 to cause memory device 130 to perform another select gate scan 204 on the refreshed memory device select gates 225. In some embodiments, if the failed bit count for the second select gate scan still exceeds the refresh threshold, adaptive select gate scanning component 113 retires the memory portion. For example, adaptive select gate scanning component 113 can use a select gate refresh count to determine a number of times the memory portion has been refreshed. In such an example, adaptive select gate scanning component 113 can retire the memory portion in response to the select gate refresh count satisfying a refresh count threshold. In such embodiments, adaptive select gate scanning component 113 increments the select gate refresh count in response to performing the refresh operation.

In some embodiments, the refresh threshold corresponds with a number of failed bits. For example, the refresh threshold can represent a maximum allowable number of failed bits for a given select gate bias voltage 214 (e.g., maximum allowable number of bits above the select gate bias voltage). In some embodiments adaptive select gate scanning component 113 determines the refresh threshold using the scan address. For example, adaptive select gate scanning component 113 retrieves the refresh threshold from a look-up table using the scan address for memory device select gates 225. In some embodiments, adaptive select gate scanning component 113 determines the refresh threshold using the select gate type. In some embodiments, adaptive select gate scanning component 113 determines the refresh threshold using the program erase cycle count. For example, adaptive select gate scanning component 113 retrieves the refresh threshold from a look-up table using the program erase cycle count for memory device select gates 225.

In some embodiments, adaptive select gate scanning component 113 determines whether failed bit count 206 satisfies a reallocation threshold. For example, adaptive select gate scanning component 113 retrieves a reallocation threshold associated with memory device select gates 225 and determines whether failed bit count 206 is greater than the retrieved reallocation threshold. In such an example, if failed bit count 206 is greater than the retrieved reallocation threshold, adaptive select gate scanning component 113 causes memory device 130 to begin reallocating the data stored in the memory portion associated with memory device select gates 225 to another memory portion. In some embodiments adaptive select gate scanning component 113 determines the reallocation threshold using the scan address. For example, adaptive select gate scanning component 113 retrieves the reallocation threshold from a look-up table using the scan address for memory device select gates 225. In some embodiments, the reallocation threshold is less than the refresh threshold. For example, adaptive select gate scanning component 113 can use a reallocation threshold that is less than the refresh threshold so that the data stored in the memory portion is already being reallocated before the memory portion is failing to the point of requiring a refresh. In some embodiments, adaptive select gate scanning component 113 determines the reallocation threshold using the select gate type. In some embodiments, adaptive select gate scanning component 113 determines the reallocation threshold using the program erase cycle count.

In some embodiments, adaptive select gate scanning component 113 updates the scan frequence for the memory portion using the failed bit count 206. For example, adaptive select gate scanning component 113 can determine that the memory portion scanned is degrading and reduce the program erase cycle threshold for that memory portion, thereby increasing the frequency of select gate scanning.

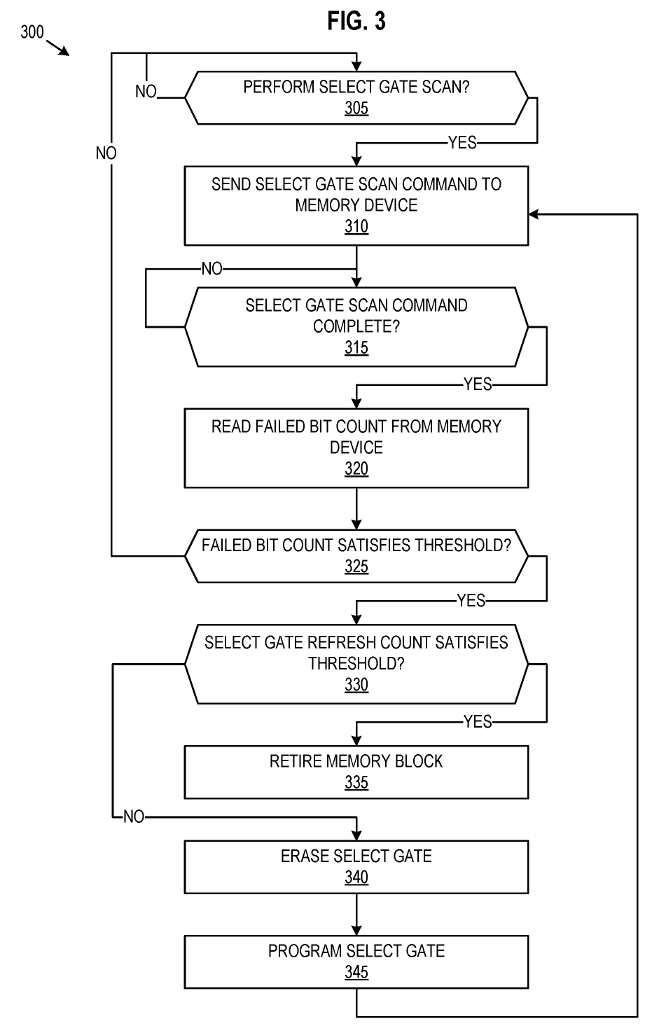

FIG. 3 is a flow diagram of an example method 300 to perform select gate scanning using failed bit counts, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the adaptive select gate scanning component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing device determines whether to perform a select gate scan. For example, adaptive select gate scanning component 113 determines whether the program erase cycle count for a memory portion satisfies the program erase cycle threshold for that memory portion. In some embodiments, adaptive select gate scanning component 113 retrieves the program erase cycle count and/or program erase cycle threshold from memory using the memory portion. For example, adaptive select gate scanning component 113 uses an address of the memory portion to retrieve the program erase cycle count and program erase cycle threshold and determines whether the program erase cycle count exceeds the program erase cycle threshold.

In some embodiments, adaptive select gate scanning component 113 determines to perform a select gate scan in response to detecting a memory operation failure. For example, in response to detecting a memory read, write, or erase failure on the memory portion, adaptive select gate scanning component 113 determines to perform the select gate scan on the memory portion. If the processing device determines to perform a select gate scan, the method 300 proceeds to operation 310. If the processing device does not determine to perform a select gate scan, the method 300 returns to operation 305.

At operation 310, the processing device sends a select gate scan command to the memory device. For example, adaptive select gate scanning component 113 sends select gate scan command 202 to memory device 130. In some embodiments, adaptive select gate scanning component 113 includes a select gate bias voltage 214 in the select gate scan command 202. For example, adaptive select gate scanning component 113 determines a select gate bias voltage 214 using a select gate type for the memory portion. In some embodiments, adaptive select gate scanning component 113 includes a scan address in the select gate scan command 202. Further details regarding sending a select gate scan command are discussed with reference to FIG. 2.

At operation 315, the processing device determines whether the select gate scan command is complete. For example, adaptive select gate scanning component 113 determines whether memory device 130 is busy performing the select gate scan 204 or whether memory device 130 is ready for another memory operation. Further details regarding determining whether the select gate scan command is complete are discussed with reference to FIG. 2. If the processing device determines that the select gate scan command is complete, the method 300 proceeds to operation 320. If the processing device does not determine that the select gate scan command is complete, the method 300 returns to operation 315.

At operation 320, the processing device reads the failed bit count from the memory device. For example, adaptive select gate scanning component 113 receives failed bit count 206 from memory device 130. In some embodiments, select gate scanning component 113 retrieves failed bit count 206 from memory cache 215 in response to determining that memory device 130 has completed the select gate scan 204. In some embodiments, memory device 130 sends failed bit count 206 to select gate scanning component 113. Further details regarding reading the failed bit count from the memory device are discussed with reference to FIG. 2.

At operation 325, the processing device determines whether the failed bit count satisfies a threshold. For example, adaptive select gate scanning component 113 determines whether failed bit count 206 meets or exceeds a refresh threshold for the memory portion. The failed bit count 206 represents memory locations with select gate threshold voltages that are higher than a bias voltage. As discussed above, select gate threshold voltages that are too high may result in select gates that cannot be activated even with higher select gate bias voltages which pinches off the associated channel, resulting in memory operation failure and potentially permanent loss of data.

In some embodiments, adaptive select gate scanning component 113 retrieves the refresh threshold for the memory portion using the scan address. In some embodiments, adaptive select gate scanning component 113 determines whether the failed bit count satisfies a reallocation threshold. In such embodiments, rather than performing a refresh operation (e.g., proceeding to operation 340), the processing device starts a transfer of data stored in the memory portion to a different memory portion. Further details regarding determining whether the failed bit count satisfies a threshold are discussed with reference to FIG. 2. If the processing device determines that the failed bit count satisfies the threshold, the method 300 proceeds to operation 330. If the processing device does not determine that the failed bit count satisfies the threshold, the method 300 returns to operation 305.

At operation 330, the processing device determines whether the select gate refresh count satisfies a refresh count threshold. For example, adaptive select gate scanning component 113 determines the select gate refresh count as a number of times that the select gates of the memory portion have been refreshed. In such an example, adaptive select gate scanning component 113 compares the select gate refresh count to the refresh count threshold and determines that the select gate refresh count satisfies the refresh count threshold if the select gate refresh count is greater than the refresh count threshold. If the processing device determines that the select gate refresh count satisfies the threshold, the method 300 proceeds to operation 335. If the processing device determines that the select gate refresh count does not satisfy the threshold, the method 300 proceeds to operation 340.

At operation 335, the processing device retires the memory block. For example, adaptive select gate scanning component 113 marks the memory portion associated with the failed select gate scan as retired and transfers data from the retired portion to a different memory portion.

At operation 340, the processing device erases the select gate(s). For example, adaptive select gate scanning component 113 performs an erase operation on the select gates for the memory portion as part of a refresh operation.

At operation 345, the processing device programs the select gate(s). For example, adaptive select gate scanning component 113 reprograms the select gates for the memory portion after performing an erase operation. In some embodiments, adaptive select gate scanning component 113 increments the select gate refresh count in response to completing the refresh operation (e.g., performing an erase operation following by a program operation). In some embodiments, as shown in FIG. 3, adaptive select gate scanning component 113 sends another select gate scan command 202 in response to completing the refresh operation.

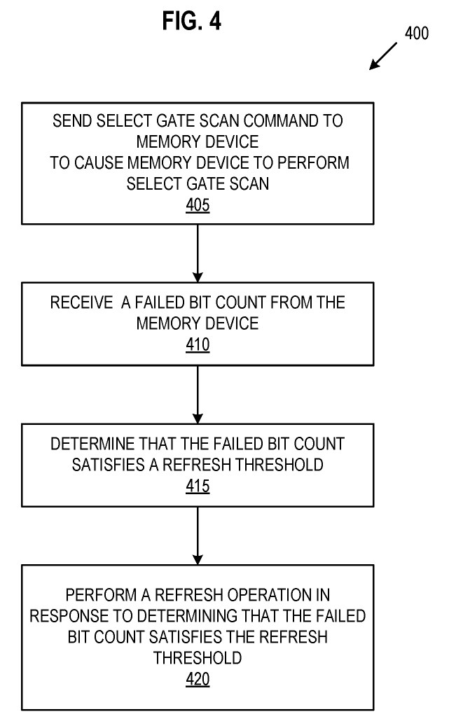

FIG. 4 is a flow diagram of an example method 400 to perform select gate scanning using failed bit counts, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the adaptive select gate scanning component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device sends a select gate scan command to a memory device causing the memory device to perform a select gate scan. For example, adaptive select gate scanning component 113 sends select gate scan command 202 to memory device 130 causing memory device 130 to perform a select gate scan 204 on memory device select gates 225 of memory device 130. In some embodiments, the select gate scan command includes a select gate bias voltage and/or a scan address. Further details regarding sending a select gate scan command are discussed with reference to FIGS. 2 and 3.

At operation 410, the processing device receives a failed bit count from the memory device. For example, adaptive select gate scanning component 113 retrieves failed bit count 206 from memory cache 215 of memory device 130 in response to memory device 130 performing the select gate scan 204 on memory device select gates 225. In some embodiments, adaptive select gate scanning component 113 receives failed bit count 206 from memory device 130. Further details regarding receiving the failed bit count are described with reference to FIGS. 2 and 3.

At operation 415, the processing device determines that the failed bit count satisfies a refresh threshold. For example, adaptive select gate scanning component 113 determines that failed bit count 206 satisfies a refresh threshold for the memory portion. In some embodiments, adaptive select gate scanning component 113 determines the refresh threshold using the address of the memory portion. Further details regarding determining that the failed bit count satisfies a refresh threshold are described with reference to FIGS. 2 and 3.

At operation 420, the processing device performs a refresh operation in response to determining that the failed bit count satisfies the refresh threshold. For example, adaptive select gate scanning component 113 performs an erase operation on memory device select gates 225 of memory device 130 followed by a program operation reprogramming memory device select gates 225. In some embodiments, adaptive select gate scanning component 113 sends another select gate scan command in response to memory device 130 performing the refresh operation. Further details regarding performing a refresh operation are discussed with reference to FIGS. 2 and 3.

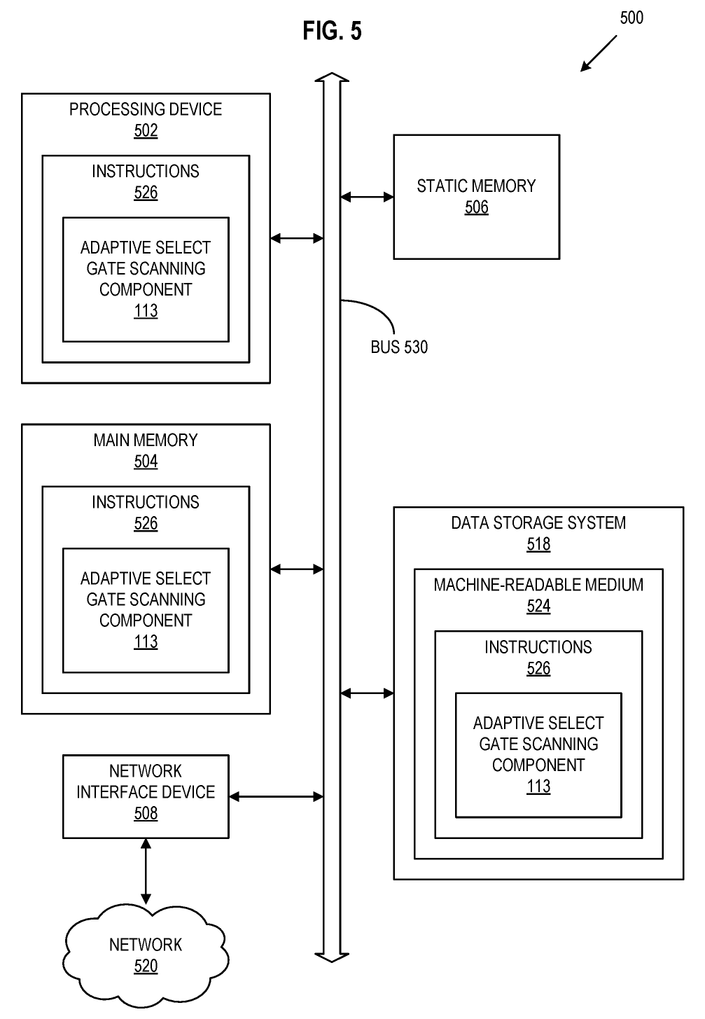

FIG. 5 illustrates an example machine of a computer system 500 within which a set of instructions for causing the machine to perform any one or more of the methodologies discussed herein can be executed. In some embodiments, the computer system 500 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the adaptive select gate scanning component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a smart device, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random-access memory (DRAM) such as synchronous DRAM (SDRAM) or Rambus DRAM (RDRAM), etc.), a static memory 506 (e.g., flash memory, static random-access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526, constituting machine-readable storage media, can also reside, completely or at least partially, within the main memory 504 and/or within the processing device 502 during execution thereof by the computer system 500, the main memory 504 and the processing device 502. The machine-readable storage medium 524, data storage system 518, and/or main memory 504 can correspond to the memory subsystem 10 of FIG. 1.

In one embodiment, the instructions 526 include instructions to implement functionality corresponding to an adaptive select gate scanning component (e.g., adaptive select gate scanning component 113 of FIG. 1). While the machine-readable storage medium 524 is shown in an example embodiment to be a single medium, the term “machine-readable storage medium” should be taken to include a single medium or multiple media that store the one or more sets of instructions (e.g., instructions 526). The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 300 and/or 400 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random-access memories (RAMs), EPROMs, EEPROMs, magnetic or optical cards, or any type of media suitable for storing electronic instructions coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
sending a select gate scan command to a memory device to cause the memory device to perform a select gate scan at a select gate bias voltage on a memory portion of the memory device;
receiving, from the memory device, a failed bit count, wherein the failed bit count is a number of bits of the memory portion with threshold voltages exceeding the select gate bias voltage;
determining that the failed bit count satisfies a refresh threshold; and
performing a refresh operation on the memory portion in response to determining that the failed bit count satisfies the refresh threshold.

2. The method of claim 1, further comprising:
determining a select gate type for the select gate scan command; and
determining the select gate bias voltage using the select gate type, wherein sending the select gate scan command includes the select gate bias voltage.

3. The method of claim 1, further comprising:
determining a scan address for a subset of the memory portion using defectivity information for the memory portion, wherein the select gate scan command further includes the scan address and wherein the select gate scan command including the scan address causes the memory device to perform a select gate scan at a select gate bias voltage on the subset of the memory portion.

4. The method of claim 3, wherein determining to perform the select gate scan on the memory portion comprises:
determining a program erase cycle count for the memory portion; and
determining that the program erase cycle count satisfies a program erase cycle threshold.

5. The method of claim 4, further comprising:
determining the select gate bias voltage using the program erase cycle count.

6. The method of claim 3, further comprising:
determining that a scan time for the memory portion satisfies a scan time threshold, wherein determining the scan address is in response to determining that the scan time satisfies the scan time threshold.

7. The method of claim 1, further comprising:
sending, in response to performing the refresh operation, a second select gate scan command to the memory device to cause the memory device to perform a second select gate scan on the memory portion;
receiving, from the memory device, a second failed bit count;
determining that the second failed bit count satisfies the refresh threshold; and
retiring the memory portion in response to determining that the second failed bit count satisfies the refresh threshold.

8. The method of claim 1, further comprising:
sending a second select gate scan command including a second select gate bias voltage to the memory device to cause the memory device to perform a second select gate scan at the second select gate bias voltage on a second memory portion of the memory device;
receiving, from the memory device, a second failed bit count, wherein the second failed bit count is a number of bits of the second memory portion with threshold voltages exceeding the second select gate bias voltage;
determining that the second failed bit count satisfies a reallocation threshold; and
reallocating data stored in the second memory portion in response to the failed bit count satisfying the reallocation threshold.

9. A non-transitory computer-readable storage medium comprising instructions that, when executed by a processing device, cause the processing device to:
send a select gate scan command to a memory device to cause the memory device to perform a select gate scan at a select gate bias voltage on a memory portion of the memory device;
receive, from the memory device, a failed bit count, wherein the failed bit count is a number of bits of the memory portion with threshold voltages exceeding the select gate bias voltage;
determine that the failed bit count satisfies a refresh threshold; and
perform a refresh operation on the memory portion in response to determining that the failed bit count satisfies the refresh threshold.

10. The non-transitory computer-readable storage medium of claim 9, wherein the processing device is further to:
determine a select gate type for the select gate scan command; and
determine the select gate bias voltage using the select gate type, wherein sending the select gate scan command includes the select gate bias voltage.

11. The non-transitory computer-readable storage medium of claim 9, wherein the processing device is further to:
determine a scan address for a subset of the memory portion using defectivity information for the memory portion, wherein the select gate scan command further includes the scan address and wherein the select gate scan command including the scan address causes the memory device to perform a select gate scan at a select gate bias voltage on the subset of the memory portion.

12. The non-transitory computer-readable storage medium of claim 11, wherein determining to perform the select gate scan on the memory portion comprises:
determine a program erase cycle count for the memory portion; and
determine that the program erase cycle count satisfies a program erase cycle threshold.

13. The non-transitory computer-readable storage medium of claim 12, wherein the processing device is further to:
determine the select gate bias voltage using the program erase cycle count.

14. The non-transitory computer-readable storage medium of claim 11, wherein the processing device is further to:
determine that a scan time for the memory portion satisfies a scan time threshold, wherein determining the scan address is in response to determining that the scan time satisfies the scan time threshold.

15. The non-transitory computer-readable storage medium of claim 9, wherein the processing device is further to:
send, in response to performing the refresh operation, a second select gate scan command to the memory device to cause the memory device to perform a second select gate scan on the memory portion;
receive, from the memory device, a second failed bit count;
determine that the second failed bit count satisfies the refresh threshold; and
retire the memory portion in response to determining that the second failed bit count satisfies the refresh threshold.

16. The non-transitory computer-readable storage medium of claim 9, wherein the processing device is further to:
send a second select gate scan command including a second select gate bias voltage to the memory device to cause the memory device to perform a second select gate scan at the second select gate bias voltage on a second memory portion of the memory device;
receive, from the memory device, a second failed bit count, wherein the second failed bit count is a number of bits of the second memory portion with threshold voltages exceeding the second select gate bias voltage;
determine that the second failed bit count satisfies a reallocation threshold; and
reallocate data stored in the second memory portion in response to the failed bit count satisfying the reallocation threshold.

17. A system comprising:
a plurality of memory devices; and
a processing device, operatively coupled with the plurality of memory devices, to:
determine a select gate type for a select gate scan command;
determine a select gate bias voltage using the select gate type;
send the select gate scan command including the select gate bias voltage to a memory device to cause the memory device to perform a select gate scan at the select gate bias voltage on a memory portion of the memory device;
receive, from the memory device, a failed bit count, wherein the failed bit count is a number of bits of the memory portion with threshold voltages exceeding the select gate bias voltage;
determine that the failed bit count satisfies a refresh threshold; and
perform a refresh operation on the memory portion in response to determining that the failed bit count satisfies the refresh threshold.

18. The system of claim 17, wherein the processing device is further to:
determine a scan address for a subset of the memory portion using defectivity information for the memory portion, wherein the select gate scan command further includes the scan address and wherein the select gate scan command including the scan address causes the memory device to perform a select gate scan at a select gate bias voltage on the subset of the memory portion; and
determine that a scan time for the memory portion satisfies a scan time threshold, wherein determining the scan address is in response to determining that the scan time satisfies the scan time threshold.

19. The system of claim 17, wherein determining to perform the select gate scan on the memory portion comprises:
determine a program erase cycle count for the memory portion; and
determine that the program erase cycle count satisfies a program erase cycle threshold and wherein the processing device is further to determine the select gate bias voltage using the program erase cycle count.

20. The system of claim 17, wherein the processing device is further to:
send, in response to performing the refresh operation, a second select gate scan command to the memory device to cause the memory device to perform a second select gate scan on the memory portion;
receive, from the memory device, a second failed bit count;
determine that the second failed bit count satisfies the refresh threshold; and
retire the memory portion in response to determining that the second failed bit count satisfies the refresh threshold.
